(19) United States
(12) Patent Application Publication
(10) Pub. No.: US 2025/0232946 A1
(43) Pub. Date: Jul. 17, 2025

(54) CHARGED PARTICLE BEAM DEVICE, AND MEASUREMENT METHOD

(71) Applicant: HITACHI HIGH-TECH CORPORATION, Minato-ku, Tokyo (JP)

(72) Inventors: Minami UCHIHO, Tokyo (JP); Yasuhiro SHIRASAKI, Tokyo (JP); Kazufumi YACHI, Tokyo (JP)

(21) Appl. No.: 18/853,804

(22) PCT Filed: May 25, 2022
(86) PCT No.: PCT/JP2022/021468

§ 371 Date: Oct. 3, 2024

(51) Int. Cl. H01J 37/22; H01J 37/244; H01J 37/28

(52) U.S. Cl. CPC H01J 37/226; H01J 37/244; H01J 37/28; H01J 2237/2448; H01J 2237/24564; H01J 2237/2817

(57) ABSTRACT

A purpose of the invention is to control a charged portion according to a structure of a transistor formed on a semiconductor material, so as to measure on/off characteristics of the transistor by irradiation with a charged particle beam and irradiation with light. A charged particle beam device according to the invention turns on a transistor formed on a semiconductor material by irradiating a gate of the transistor with a charged particle beam, and initializes charges of the transistor by irradiating the transistor with light, thereby controlling a conductive state of the transistor (see FIG. 4).

### TECHNICAL FIELD

The present invention relates to a technique of performing a measurement by irradiating a sample with a charged particle beam.

### BACKGROUND ART

A charged particle beam device such as an electron microscope or an ion microscope is used for observation of various samples having a fine structure. For example, for a purpose of process management in a manufacturing process of a semiconductor device, a scanning electron microscope, which is one of charged particle beam devices, is applied for a measurement such as a dimension measurement or a defect inspection of a semiconductor device pattern formed on a semiconductor wafer as a sample.

The following PTL 1 discloses an example of a technique of performing a measurement by irradiating a sample with a charged particle beam. PTL 1 discloses that a charged state of the sample is controlled by irradiating the sample with a light beam in addition to the charged particle beam.

### CITATION LIST

### Patent Literature

PTL 1: U.S. Pat. No. 7,205,539

### SUMMARY OF INVENTION

### Technical Problem

When a semiconductor device (such as a transistor) is formed on a semiconductor material, it may be necessary to control the charged state at a specific position of the device. For example, when a gate of a specific transistor is turned on or turned off, on/off characteristics (how much electrical signal needs to be applied to turn the transistor on or off) of the transistor may be measured. Such a measurement is typically performed by electrically connecting a measurement probe to the device.

It is considered whether the same measurement can be performed by controlling the charged state of the semiconductor device (that is, by controlling the number of charges held by the semiconductor device). However, in the related art as disclosed in PTL 1, it is not possible to freely select (or not to consider) a portion where the charges are controlled according to a structure of the semiconductor device. Therefore, in the related art, it is difficult to implement the on/off characteristics of the semiconductor device by the irradiation with the charged particle beam and the irradiation with the light.

The invention has been made in view of the above problems, and an object thereof is to control a charged portion according to a structure of a transistor formed on a semiconductor material, so as to measure on/off characteristics of the transistor by irradiation with a charged particle beam and irradiation with light.

### Solution to Problem

A charged particle beam device according to the invention turns on a transistor formed on a semiconductor material by irradiating a gate of the transistor with a charged particle beam, and initializes charges of the transistor by irradiating the transistor with light, thereby controlling a conductive state of the transistor.

### Advantageous Effects of Invention

According to the charged particle beam device of the invention, by controlling a charged portion according to a structure of a transistor formed on a semiconductor material, on/off characteristics of the transistor can be measured by irradiation with a charged particle beam and light.

### BRIEF DESCRIPTION OF DRAWINGS

FIG. 1 is a block diagram showing a configuration of a charged particle beam device 1 according to Embodiment 1.

FIG. 2 shows four configuration examples of a light source 131 and a light adjustment unit 132.

FIG. 3 is a flowchart showing a procedure in which the charged particle beam device 1 observes a sample 122.

FIG. 4 is a diagram showing a method for controlling a charged state of a transistor formed on the sample 122 by light irradiation.

FIG. 5 is an example of an in-plane distribution created by a calculation unit 148 in S108.

FIG. 6 is a diagram showing an operation example when the charged particle beam device 1 measures a parasitic capacitance between gates of transistors.

FIG. 7 is a flowchart showing a procedure in which the charged particle beam device 1 observes the sample 122.

FIG. 8 is an example of a user interface presented by the calculation unit 148 via a display unit 155.

### DESCRIPTION OF EMBODIMENTS

### Embodiment 1

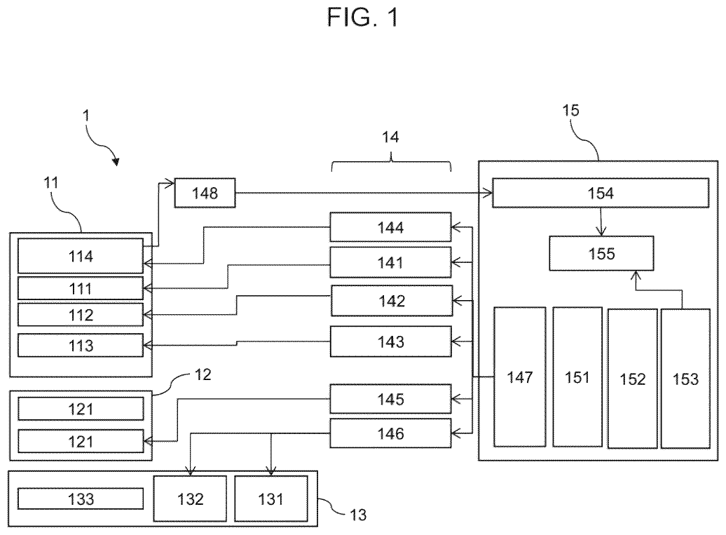

FIG. 1 is a block diagram showing a configuration of a charged particle beam device 1 according to Embodiment 1 of the invention. The charged particle beam device 1 includes an electron optical system 11, a stage mechanism system 12, a light irradiation system 13, a control system 14, and an operation system 15.

The electron optical system 11 includes an electron gun 111, a deflector 112, an electron lens 113, and an electron detector 114. The stage mechanism system 12 is implemented by placing a sample 122 on an XYZ stage 121. An inside of a housing of the electron optical system 11 is controlled to a high vacuum, and the stage mechanism system 12 is provided. The light irradiation system 13 includes a light source 131 and a light adjustment unit 132, and the sample 122 is irradiated with light via a light introduction unit 133. The control system 14 includes an electron gun control unit 1411, a deflection signal control unit 142, an electron lens control unit 143, a detector control unit 144, a stage position control unit 145, a light control unit 146, a control command unit 147, and a calculation unit 148. The control command unit 147 controls a writing of a control value to each control unit based on input information received from a sequence control unit 151.

An electron beam accelerated by the electron gun 111 is focused by the electron lens 113, and the sample 122 is irradiated with the electron beam. An irradiation position on the sample 122 is controlled by the deflector 112. The electron beam is controlled according to an acceleration voltage, an irradiation current, a deflection condition, and an electron lens condition that are set by a measurement item setting unit 152.

The control command unit 147 is a functional block that controls components of the charged particle beam device 1. The control command unit 147 sends an operation command to the detector control unit 144, the electron gun control unit 141, and the like, based on observation conditions received from, for example, the sequence control unit 151. Each control command system controls the stage mechanism system 12 based on, for example, light or electronic conditions received from the sequence control unit 151 to move the sample 122 to a predetermined position. The control command unit 147 controls a detection process of emitted electrons by the electron detector 114 by controlling a supply of power to the electron detector 114, a supply of a control signal, and the like via the detector control unit 144. The control command unit 147 transmits information on light irradiation conditions such as a wavelength, a light amount, and an irradiation timing to the light control unit 146 based on conditions input by the measurement item setting unit 152, and controls operations of the light source 131, the light adjustment unit 132, and the like. More specifically, for example, the light control unit 146 controls the light amount and the wavelength of the light emitted from the light source 131. The light control unit 146 instructs the light adjustment unit 132 to adjust a traveling direction and polarization of the light emitted from the light source 131. The light control unit 146 may be implemented by, for example, a manual operation, or may be implemented by, for example, a program executed by a personal computer on which a processor such as a CPU is mounted. The control command unit 147 may be implemented by, for example, a field-programmable gate array (FPGA) or an application specific integrated circuit (ASIC).

The light emitted from the light source 131 is emitted to a position on a surface of the sample 122 via the light introduction unit 133. As the light source 131, a light source capable of emitting lasers having a plurality of wavelengths or a light source capable of emitting lasers having a single wavelength is mounted for each necessary wavelength in the present embodiment. The light introduction unit 133 has a slit configuration, and can freely control a light shape. Accordingly, it is possible to control a position to be irradiated and a position to be irradiated according to a pattern.

In addition to the above, the operation system 15 includes an output unit 154 and a display unit 155. The output unit 154 outputs a processing result obtained by the calculation unit 148 in, for example, an appropriate data format. The display unit 155 displays the processing result obtained by the calculation unit 148 on a screen, for example, on a user interface to be described later.

A device information input unit 153 of the operation system 15 is a block having a function of inputting a structure of a sample to be observed and circuit information. By inputting CAD information or the like used at the time of designing a pattern of a device, a size of each pattern and electrical circuit information are associated with each other, and accordingly, irradiation positions of the electron beam and the light are controlled. At this time, a form of inputting the circuit information of the pattern and information such as the size is not particularly designated as long as coordinates of the pattern, the circuit information, and information such as a connection relationship of the patterns can be known, and may be, for example, CAD data or only data of a character string whose coordinates and circuit structure can be known. Even when the CAD data is not used, a circuit designation of the patterns can be performed. An example of a designation procedure at this time is shown. (1) An SEM image of an inspection portion is acquired, and (2) a signal obtained from the electron detector 114 is replaced with gradation information by a processing unit and the calculation unit, and the gradation information is displayed on the display unit 155 via the output unit 154. (3) On a GUI to be described later, a user sorts types of the patterns, and information is sent to the device information input unit 153. According to this flow, it is also possible to designate the types of the patterns of the observation position.

The measurement item setting unit 152 refers to device information input by the device information input unit 153 and generates conditions of light and an electron beam necessary for implementing an inspection item designated on the GUI. The sequence control unit 151 creates a measurement sequence based on the conditions of the light and the electron beam set by the measurement item setting unit 152. The sequence control unit 151 generates an irradiation sequence, and transmits an instruction signal to the control system. When a test item to be inspected is selected by the measurement item setting unit 152, the irradiation sequences of the light and the electron beam are generated. At this time, the user can customize the conditions of the light and the electron beam on the GUI to be described later. By selecting a sequence visualization button on the GUI, flows of the irradiation sequences of the light and the electron beam can be visually checked. The user may freely set irradiation timings of the light and the electron beam by himself/herself.

The control command unit 147 controls the detector control unit 144, the electron gun control unit 141, the deflection signal control unit 142, the electron lens control unit 143, the stage position control unit 145, the light control unit 146, and the like according to the sequence designated by the sequence control unit.

The light control unit 146 controls light parameters such as the wavelength, the irradiation amount, and peak power of the light. The light control unit 146 includes the light source 131 and the light adjustment unit 132. The light source 131 may be a white light source, a semiconductor diode laser, or a solid-state laser, and may be a light source capable of emitting other light. The light parameters adjusted by the light adjustment unit 132 include, for example, a light amount, a wavelength, a polarization plane, an irradiation angle to the sample, a pulse laser/continuous wave (CW) laser, and a repetition rate (in a case of a pulse laser). The light adjustment unit 132 also has a function of controlling an irradiation timing of the light according to the sequence information generated by the measurement item setting unit 152 and the sequence control unit 151 and performing irradiation. A mechanism having a function of the irradiation timing of the light may be a mechanical shutter, may be blocked by an electro optical element or an acoustic optical element, or may be a mechanism capable of implementing switching control of other light.

The electron optical system 11 emits the electron beam under the acceleration voltage, the irradiation current, the deflection condition, and the electron lens condition that are set by the measurement item setting unit 152. An irradiation timing of the electron beam is controlled by controlling timings of irradiation and non-irradiation based on the sequence generated by the measurement item setting unit 152 and the sequence control unit 151. The electron beam accelerated by the electron gun 111 is focused by the electron lens 113, and the sample 122 is irradiated with the electron beam. A position where the sample 122 is irradiated with the electron beam, and an observation magnification are controlled by the deflector 112.

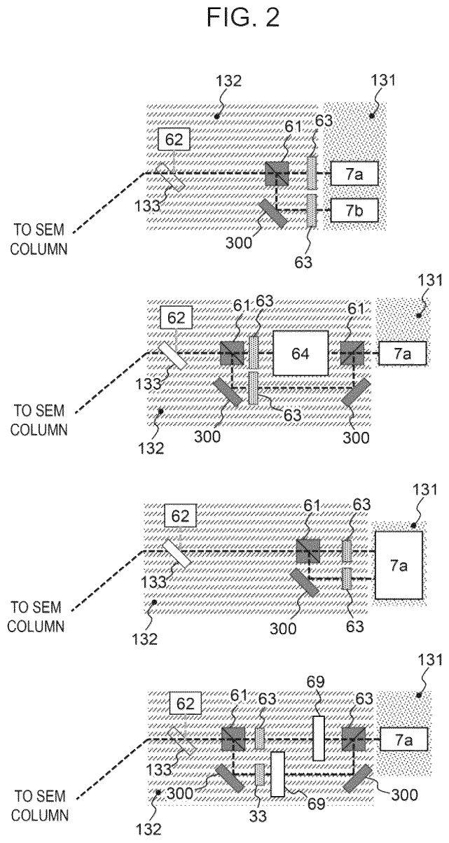

FIG. 2 shows four configuration examples of the light source 131 and the light adjustment unit 132. In a first configuration example, the light source 131 includes two light sources 7a and 7b. A laser emitted from the light source 7b is reflected by a reflection mirror 300 and a beam splitter 61, and joins an optical path of a laser emitted from the light source 7a. The light source 7a and the light source 7b may emit light having the same wavelength, or may be implemented by adjusting an irradiation output for each wavelength. In order to be capable of adjusting the irradiation amount for each wavelength, a light reducer 63 configured with an ND filter or the like capable of adjusting a light reduction amount is provided on an optical path of each wavelength. Similarly, there is an optical attenuator as an optical system for controlling an average output. As the light adjustment unit 132, a pulse picker or the like using an electro-optical effect element or a magneto-optical effect element may be used to control a frequency of a pulse or the number of irradiation pulses. A pulse width may be controlled by using a pulse dispersion control optical system configured with a prism pair as the light adjustment unit 132. As the light adjustment unit 132, a light condensing lens may be used to control an irradiation region of a light pulse. The irradiation amount of each wavelength is detected by an irradiation light detector 62 set in the middle of the optical path. The irradiation amount may be measured by a photodetector type of irradiation light detector or a thermal type of irradiation light detector as an example of the irradiation light detector 62.

In a second configuration example in FIG. 2, light having a plurality of wavelengths is generated from one light source 7a using a wavelength converter 64 formed of a nonlinear optical crystal or the like. A light reducer 63 is provided in each optical path, such that irradiation amounts of Seed light and secondary harmonic generation (SHG) light can be adjusted.

A third configuration example in FIG. 2 shows an optical path configuration when a laser capable of emitting lasers having a plurality of wavelengths from one laser is used. A fourth configuration example in FIG. 2 shows an optical path configuration when a light source having a plurality of wavelength components, such as the white light source, is used. In order to select a plurality of wavelengths from the white light source, the optical path is split into two optical paths by the beam splitter 61. Lasers having a plurality of wavelengths are generated by providing a filter 69 according to the laser having the wavelength to be emitted. The filter 69 is an optical filter such as a band-pass filter or a notch filter.

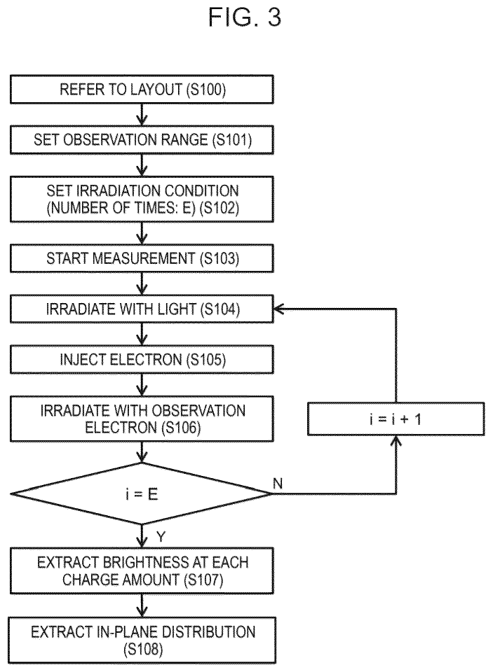

FIG. 3 is a flowchart showing a procedure in which the charged particle beam device 1 observes the sample 122. Hereinafter, each step in FIG. 3 will be described. In this description, an on state of a transistor is defined as a state in which charges are supplied to a gate portion up to a gate voltage when a designated current flows between a source and a drain, and an off state of the transistor is defined as a state in which a voltage due to the charging of the gate portion is equal to or lower than a gate threshold voltage.

### (FIG. 3: Step S100)

The control command unit 147 determines a type, a pattern, and an inspection item of a device to be inspected. Data on the type of the device and the device pattern may be designated based on the CAD data or information obtained by actually observing an SEM image of an observation position.

### (FIG. 3: Step S101)

The control command unit 147 designates a portion of the device pattern to be observed, a size of a field of view, the number of inspection chips, and the like (observation range) based on the device pattern and a chip layout.

### (FIG. 3: Step S102)

The control command unit 147 sets a range of the number of charges to be injected and irradiation conditions of light. For the electron beam to be emitted, an irradiation energy of the electron beam to be injected into the designated pattern, a minimum value and a maximum value of the charges, and a step amount are determined. At this time, an electron beam condition for injecting the electron beam into the pattern and the condition of the electron beam for the observation may not be the same. These electron beams may be output from the same electron source and electron optical system, or may be output from different electron sources and optical systems. Alternatively, an electron beam output from one electron source may be divided into a plurality of electron beams, and each of the electron beams may be controlled and emitted.

### (FIG. 3: Step S102: Supplement)

In this step, the light irradiation condition as a recommended condition is set according to the inspection item input and selected in S100. Based on the information input in S100, the wavelength, the irradiation amount, and the irradiation timing of the light calculated by the sequence control unit 151 are output to the light control unit 146 according to the inspection item and the device inspection range set by the measurement item setting unit 152. If the condition is sufficient, the user checks, for example, a “light condition confirm” button on the GUI. If a correction is necessary, the light irradiation condition is corrected by alight condition input unit displayed on the GUI, and when the light condition is determined, the “light condition confirm” button is pressed. The light control unit 146 controls the light irradiation condition according to the light irradiation condition determined in the “light condition confirm”.

### (FIG. 3: Step S103)

The control command unit 147 starts the measurement according to the inspection measurement items set in S100 to S102.

### (FIG. 3: Step S104)

The light control unit 146 controls a potential by stabilizing or equalizing an initial charged state of the sample 122 by irradiating the sample 122 with light. For example, when the transistor is formed in a lattice shape on the sample 122 (semiconductor material), first, the observation position is scanned along an X direction, and an on/off state of the transistor at each observation position is measured (a specific example of measuring the on/off state based on the observation image will be described later). Next, the observation position is moved by one line in a Y direction. Every time the observation position is moved by one line in the Y direction, the light control unit 146 emits light for only resetting the charged state of the drain (and the source).

### (FIG. 3: Step S104: Supplement)

In addition to the above, the light control unit 146 may emit light for resetting the charged state of the gate when performing this step at a first time. Specific examples of the light for resetting only the drain and the light for resetting the gate will be described later.

### (FIG. 3: Step S105)

The electron optical system 11 injects charges into the sample 122 by irradiating the sample 122 with an electron beam. Charge injection conditions are set in S102. A charge injection amount is changed by a step width each time this step is performed. This step width is set in S102. By charging the gate of the transistor according to the charge injection amount, a state similar to that in which a voltage is applied to the gate is obtained. The on/off characteristics (gate threshold voltage (Vth) characteristics) of the transistor can be measured by measuring at which stage the transistor is turned on while changing the charge injection amount.

### (FIG. 3: Step S105: Supplement)

The following is considered as a modification. Photoelectron emission caused by the light irradiation may be used as a method for accumulating charges in the gate portion. When a material of the gate portion is polysilicon, photoelectrons are emitted from the gate portion by emitting light of a wavelength having a light energy equal to or higher than an ionization energy of silicon or emitting light having a peak intensity at which multiphoton excitation occurs, and accordingly positive charging occurs. The gate may be turned on using the positive charging. Therefore, step S105 in FIG. 3 may be a method for emitting light. An amount of the accumulated charges may be controlled by the light parameters such as the irradiation amount, the irradiation time, the peak intensity, and the wavelength of light.

### (FIG. 3: Step S106)

The electron optical system 11 moves the field of view to the observation position and emits the electron beam under the electron optical condition set in S103. Electrons emitted from the sample are detected by the detector 114. The calculation unit 148 generates an observation image of the observation position using a detection signal output from the detector 114. The observation image is output as data or on the GUI via the output unit 154 and the display unit 155. When the observation position is the same as the charge injection position in S105, the irradiation position may not be moved in S105 and S106. When the observation position is not the same as the charge injection position in S105, the observation position may be moved by stage movement, deflection shift of the electron beam, or the like.

### (FIG. 3: Loop Portion)

The control command unit 147 repeats S104 to S106 until the number of steps set in S102 is completed.

### (FIG. 3: Steps S107 and S108)

The calculation unit 148 acquires a luminance level of the observation image for each injected charge amount into the sample 122 (S107). The calculation unit 148 performs this process for each observation position on the sample 122. Accordingly, an in-plane distribution of the injected charge amount and the luminance level can be obtained (S108). A specific example of the in-plane distribution will be described later.

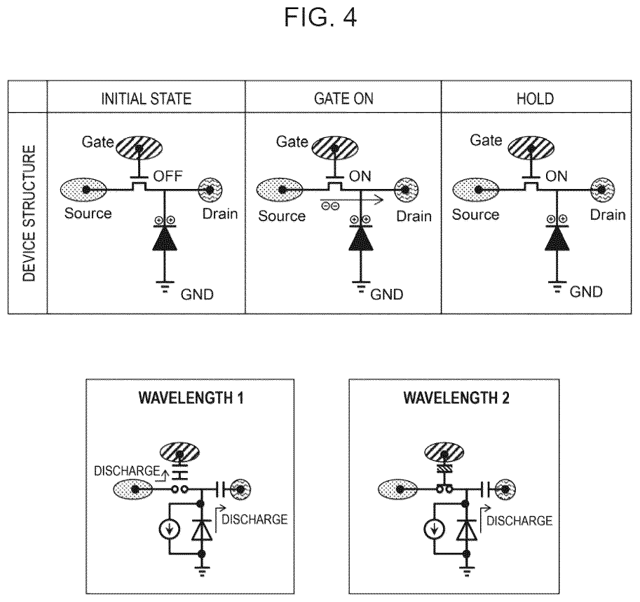

FIG. 4 is a diagram showing a method for controlling a charged state of a transistor formed on the sample 122 by the light irradiation. The transistor includes a source, a gate, and a drain. The present embodiment will be described using a structure of an n-type metal oxide semiconductor field effect transistor (MOSFET). The n-type MOSFET is formed by forming a silicon oxide film in a gate region on a p-type silicon substrate and forming a gate metal on the oxide film. In the n-type MOSFET, when a positive voltage is applied to the gate portion formed between the source and the drain, an inversion layer (n-type) is formed between the drain and the source.

When the n-type MOSFET is operated and inspected using the electron beam, the gate portion is irradiated with the electron beam having a region in which a yield of secondary electrons is 1 or more, so that the number of electrons emitted from the sample is equal to or more than the number of electrons incident on the gate portion, resulting in the positive charge. Due to the positive charge, a positive potential is applied to the gate portion. Therefore, the gate is turned on, and a flow of electrons is generated between the source and the drain. On the other hand, in the case of the P-type MOSFET, since a drain current can be generated by applying a negative voltage to the gate, the gate is negatively charged by setting the irradiation energy of the electron beam under the electron beam conditions such that the yield of the secondary electrons is less than 1, and the negative voltage is applied to the gate portion. As a method for controlling positive and negative of the voltage applied to the gate portion, the acceleration voltage of the electron beam injected into the gate portion may be controlled, or an electrode may be provided directly above the sample to indirectly apply an electric field from the outside. Further, a voltage may be applied by coming into direct contact with a terminal of a prober or the like. When the electron beam is injected into the gate portion using the electron beam, the whole pattern may be irradiated with the electron beam, or one point of the portion where the transistor is formed in designated pattern coordinates may be irradiated. Further, an irradiation method simulating a plurality of operation states may be performed by using a plurality of electron beams and simultaneously or alternately performing the irradiation under negative voltage application conditions and positive voltage application conditions according to the type of the transistors during the same observation.

When the charges accumulated in the gate portion are reset, the gate portion is generally formed on a gate insulating film, and thus the charges are removed by supplying electrons from a substrate material. Therefore, the light control unit 146 removes the charges accumulated in the insulating film by irradiating the substrate material with light having a wavelength 1 that is absorbed by the substrate material. At this time, portions formed on a joint structure are reset at the same time since the substrate materials are the same. For example, in a general dynamic random access memory (DRAM) implemented by the insulating film or the joint structure on a Si substrate, the entire accumulated charges of the DRAM structure can be controlled or reset by irradiation with light having a wavelength of 500 nm or less. In addition, the number of the charges accumulated in the gate portion can also be controlled by controlling the irradiation amount and the wavelength. When the charges of the gate portion are controlled, light having a wavelength that is directly absorbed by the gate insulating film may be emitted. By resetting the charges of the gate portion, the transistor is turned off.

A wavelength 2 is selected so as to remove charges only in a portion formed on the joint. Accordingly, only the charges accumulated in the source portion and the drain portion are reset while the charges are accumulated in the gate portion (while the gate portion is turned on).

When performing S104 for the first time, the light control unit 146 can reset the charged state of the gate portion by emitting the light having the wavelength 1. In the loop of S104 to S106, for example, the charged states of the source portion and the drain portion can be reset by emitting the light having the wavelength 2 every time the observation position is moved by one line in the Y direction. For example, when it is desired to observe characteristics such as a breakdown voltage failure and a recovery time of the joint, the detection signal from the detector 114 may be acquired after the light having the wavelength 2 is emitted. When it is desired to observe the on/off characteristic of the gate portion (how much applied voltage, that is, how much injected charge amount is required to turn on) or to reset the entire transistor, the wavelength 1 may be used.

Depending on whether the transistor is in the on state, a secondary signal level detected by the detector 114 (that is, the luminance level of the observation image at the observation position) differs. Therefore, the on/off state of the transistor can be acquired based on the detection signal level or a pixel value of the observation image. According to this, the calculation unit 148 can measure the on/off characteristics of the transistor.

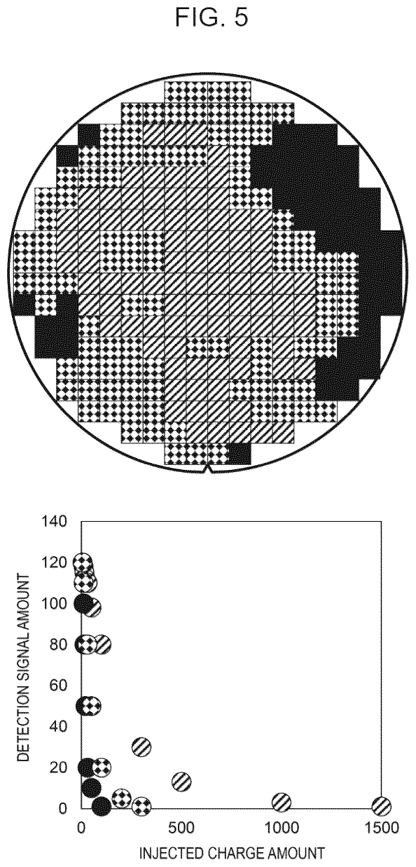

FIG. 5 is an example of an in-plane distribution created by the calculation unit 148 in S108. When the detection signal from the detector 114 is acquired for each observation position while changing the injected charge amount into the sample 122, a relationship between the injected charge amount and the detection signal as shown in a lower diagram in FIG. 5 can be obtained for each observation position on the sample 122. Accordingly, an in-plane distribution as shown in an upper diagram in FIG. 5 is obtained. For example, in portions shaded in black, the detection signal decreases rapidly when the injected charge amount is increased. In contrast, in shaded portions, the decrease in the detection signal with respect to the increase in the injected charge amount is gentle. Such a difference is caused by a fact that the characteristics of the transistor transitioning between the on/off states when the injected charge amount (that is, the voltage applied to the gate portion) is gradually increased differ for each semiconductor chip formed on the sample 122. The in-plane distribution represents a distribution of such a difference in characteristics.

The in-plane distribution as shown in FIG. 5 can be acquired without necessarily acquiring the observation image of the sample 122. That is, if the detection signal level from the detector 114 is acquired for each injected charge amount, the characteristics shown in the lower diagram in FIG. 5 can be obtained, and thus it is sufficient to use the characteristics to create the in-plane distribution. For example, when the in-plane distribution as shown in FIG. 5 is obtained only for the drain portion of the transistor, it is sufficient to acquire the detection signal level when the drain portion is irradiated with the observation electron beam. Measurement throughput can be ensured by obtaining the in-plane distribution without generating the observation image. For example, in a middle stage of the manufacturing process, the in-plane distribution as shown in FIG. 5 can be quickly obtained without stopping the process.

### Embodiment 1: Summary

The charged particle beam device 1 according to the present Embodiment 1 measures the on/off characteristics (gate threshold voltage (Vth) characteristics) with respect to the injected charge amount into the transistor based on the wavelength 1 for initializing the charged state of the gate portion of the transistor formed on the sample 122 and the wavelength 2 for initializing only the charged states of the drain portion and the source portion. Accordingly, the on/off characteristics of the transistor can be measured using the light irradiation and the charged particle beam irradiation without connecting a measurement device such as an electrical probe to the transistor.

### Embodiment 2

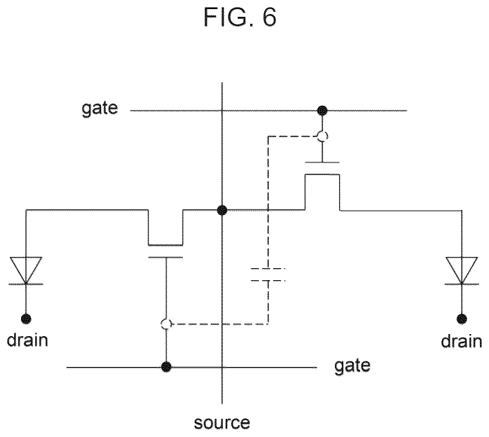

FIG. 6 is a diagram showing an operation example when the charged particle beam device 1 measures a parasitic capacitance between gates of transistors. In FIG. 6, the two transistors are connected so as to share sources or drains (in FIG. 6, source terminals are shared). The charged particle beam device 1 can measure a parasitic capacitance (a portion indicated by a dotted line in FIG. 6) between gate terminals in FIG. 6 by the following procedure. A configuration of the charged particle beam device 1 is similar to that in Embodiment 1.

The control command unit 147 irradiates the sample 122 with the electron beam so as to turn on only the gate of one of the transistors. Accordingly, for example, a charge amount sufficient for the turn-on is injected into the gate portion on a right side of FIG. 6. At this time, if the parasitic capacitance between the gate terminals is sufficiently small, only the transistor into which the charges are injected becomes conductive. On the other hand, when the parasitic capacitance is equal to or larger than a certain reference value, charges are also injected into the other gate via the parasitic capacitance, and the other transistor is conductive accordingly.

The conduction of the transistor can be detected by the detection signal level when the transistor is irradiated with the observation electron beam. That is, the detection signal from the transistor in the conductive state and the detection signal from the transistor in a non-conductive state have different signal levels. The calculation unit 148 can measure whether the parasitic capacitance as indicated by a dotted line in FIG. 6 is equal to or larger than a reference value based on the detection signal level set in each transistor in the above procedure.

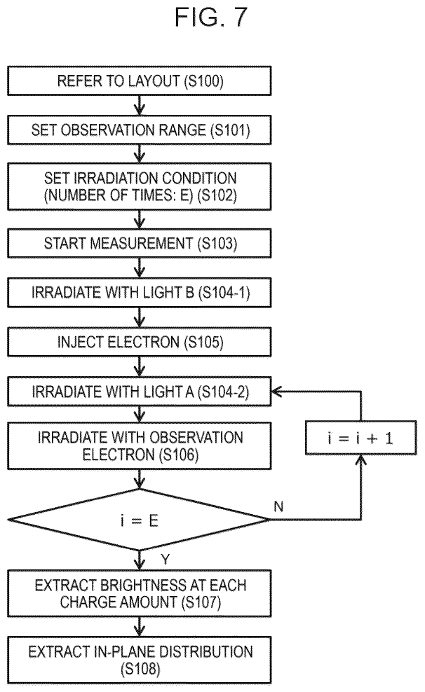

FIG. 7 shows an example of a sequence in which the irradiation with the electron beam and the irradiation with the light are performed to calculate the parasitic capacitance. The parasitic capacitance is measured by observing a time constant of a relaxation process of the injected charges. For example, an irradiation interval of the electron beam to be emitted is changed, and electrons emitted at that time are acquired by the detector 114. When the parasitic capacitance of the gate is small, the time constant becomes small, and thus a time until the stored charge amount is discharged becomes short. When the parasitic capacitance is large, the time constant becomes long. Therefore, the parasitic capacitance between the gates can be calculated by acquiring a brightness of the observation image of the gate at each irradiation interval of the electron beam. Steps similar to those in FIG. 3 are denoted by the same step numbers, and differences from FIG. 3 will be mainly described below.

In this flowchart, the parasitic capacitance is calculated by acquiring the detection signal while varying the irradiation interval (interval step of the GUI to be described later) and a current amount (irradiation current amount or pulse electron width) of the electron beam emitted in the observation electron irradiation (S106).

In step S104-1, a potential state of the entire transistor is made uniform, and in step S105, charges are injected into one gate portion. The observation position is moved to the drain portion formed by a switch such as a joint, and only the drain portion formed by the joint structure is reset in step S104-2. According to the conditions set in S102, the parasitic capacitance is calculated by acquiring the detection signal while varying the irradiation interval (interval step of the GUI to be described later) and a current amount (irradiation current amount or pulse electron width) of the electron beam emitted in the observation electron irradiation (S106). At this time, the sample 122 is irradiated with the light set in step S104-2 every time the condition such as the irradiation interval changes.

### Embodiment 2: Summary

The charged particle beam device 1 according to the Embodiment 2 measures the parasitic capacitance between wirings to the transistor based on the wavelength 1 for initializing the charged state of the gate portion of the transistor formed on the sample 122 and the wavelength 2 for initializing only the charged states of the drain portion and the source portion. Accordingly, it is possible to indirectly evaluate a distance between the wirings, film quality of the insulating film, and the like by measuring the parasitic capacitance between the wirings using the light irradiation and the charged particle beam irradiation without connecting a measurement device such as an electrical probe to the transistor.

### Embodiment 3

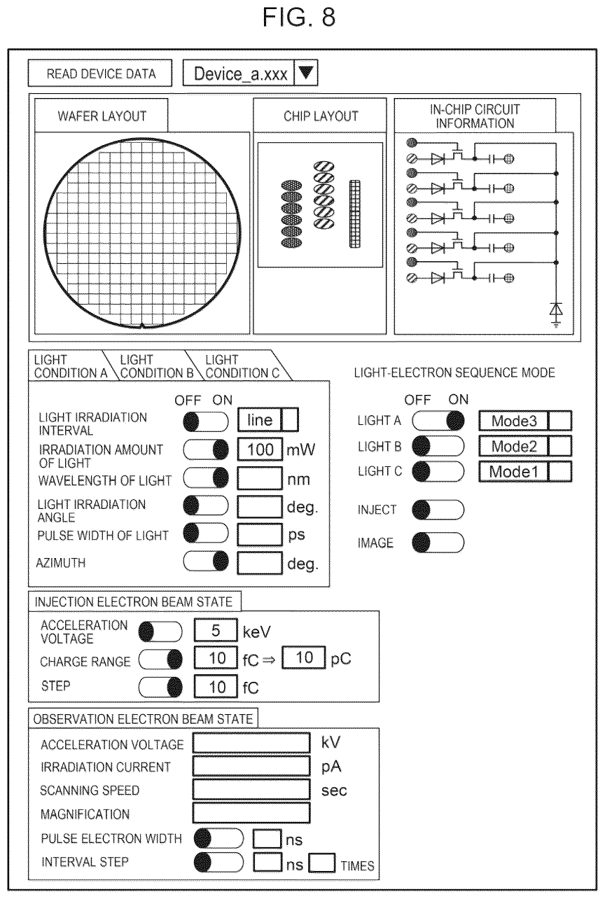

FIG. 8 is an example of a user interface presented by the calculation unit 148 via a display unit 155. The user interface (GUI) can present, for example, the following: (a) a charged particle beam irradiation condition input unit for inputting an irradiation condition of an electron beam (both for observation and for charge injection); (b) a light irradiation condition input unit for inputting an irradiation condition of light; (c) an observation image of the sample 122; (d) a result of an inspection of the sample 122 (transistor); and (e) the in-plane distribution in FIG. 5 (any one of a distribution image in an upper part and a graph in a lower part of FIG. 5).

The user can designate and input each irradiation condition in addition to viewing a measurement result on the GUI. The control command unit 147 controls each unit according to the designation input to perform the measurement sequence described with reference to FIGS. 3 and 4 (or FIG. 6).

### Regarding Modification of Invention

In the above embodiment, it is described that the in-plane distribution shown in FIG. 5 can be generated using the detection signal level even if the observation image of the sample 122 is not necessarily generated. Whether to use only the detection signal level or to generate the observation image may be switched as information used for measuring the sample 122. For example, whether to generate an observation image may be designated by the user on the GUI.

In the above embodiment, the light irradiation conditions for the wavelength 1 and the wavelength 2 that are described with reference to FIG. 4 may be switched based on whether the light is absorbed by a designated portion of the sample 122, and thus it is not necessarily required to use wavelength switching. For example, if whether the irradiated portion absorbs the light is different depending on an optical output, output switching may be performed instead of the wavelength switching. Further, the above may be combined.

In the above embodiment, the control command unit 147 and the calculation unit 148 are described as individual functional units. Alternatively, the control command unit 147 and the calculation unit 148 may be implemented as an integrated control unit. The control system 14 and the operation system 15 (and the functional units provided in the control system 14 and the operation system 15) may be implemented by hardware such as a circuit device having functions of the control system 14 and the operation system 15, or may be implemented by an arithmetic unit such as a central processing unit (CPU) executing software having the functions of the control system 14 and the operation system 15.

In the above embodiments, it is described that charges are injected into the sample or the observation image of the sample is obtained by irradiating the sample with the electron beam, but the invention is also applicable to cases where similar functions are implemented by emitting other charged particle beams.

### REFERENCE SIGNS LIST

1: charged particle beam device
11: electron optical system
114: detector
13: light irradiation system
147: control command unit
148: calculation unit

1. A charged particle beam device for irradiating a sample with a charged particle beam, the charged particle beam device comprising:
a charged particle beam irradiation unit configured to irradiate the sample with the charged particle beam;
a light irradiation unit configured to irradiate the sample with light;
a detector configured to detect a secondary particle generated from the sample by irradiating the sample with the charged particle beam and configured to output a detection signal indicating an intensity of the secondary particle; and
a calculation unit configured to process the detection signal, wherein
the sample is a transistor formed on a semiconductor material,
the charged particle beam irradiation unit irradiates a gate of the transistor with the charged particle beam and injects charges to turn on the transistor,
the light irradiation unit irradiates the transistor with the light and initializes charges of the transistor to control a conductive state of the transistor, and
the calculation unit measures an on/off characteristic of the transistor with respect to an injected charge amount into the transistor using the detection signal obtained in a process of controlling the conductive state of the transistor.

2. The charged particle beam device according to claim 1, wherein
the light irradiation unit initializes charges of the gate by irradiating the transistor with the light having a first wavelength that is absorbed by the semiconductor material or a gate insulating layer formed on the semiconductor material, and
the light irradiation unit turns off the transistor by initializing the charges of the gate.

3. The charged particle beam device according to claim 1, wherein
the light irradiation unit initializes charges of a source and a drain of the transistor while keeping the gate on by irradiating the transistor with the light having a second wavelength that is not absorbed by a gate insulating layer formed on the semiconductor material but is absorbed by the semiconductor material.

4. The charged particle beam device according to claim 2, wherein
the light irradiation unit repeats changing an irradiation amount of the charged particle beam such that the injected charge amount into the transistor changes after the charges of the gate are initialized, and
the calculation unit measures the on/off characteristic of the transistor for each injected charge amount into the transistor by acquiring the detection signal for each repetition.

5. The charged particle beam device according to claim 4, wherein
the calculation unit measures an in-plane distribution of the on/off characteristic of the transistor on the surface by performing the measurement for each position on the surface of the semiconductor material.

6. The charged particle beam device according to claim 4, wherein
the transistor is formed over a plurality of lines on the semiconductor material,
the light irradiation unit initializes the charges of the source and the drain of the transistor while keeping the gate on by irradiating the transistor with the light having a second wavelength that is not absorbed by the gate insulating layer formed on the semiconductor material but is absorbed by the semiconductor material,
the calculation unit scans a position where the detection signal is acquired along an extending direction of a first line in which the transistor is disposed, and
the light irradiation unit initializes the charges of the source and the drain of the transistor disposed along a second line by performing the initialization after acquisition of the detection signal for the first line is completed and before the calculation unit starts acquiring the detection signal along an extending direction of the second line adjacent to the first line.

7. The charged particle beam device according to claim 1, wherein
the transistor includes a first transistor and a second transistor that share a common source or drain,
the charged particle beam irradiation unit performs a parasitic capacitance evaluation sequence in which a gate of the first transistor is turned on and a gate of the second transistor is not turned on by irradiating the gate of the first transistor with the charged particle beam but not irradiating the gate of the second transistor with the charged particle beam, and
the calculation unit measures a parasitic capacitance between the gate of the first transistor and the gate of the second transistor by evaluating whether the second transistor is conductive when the parasitic capacitance evaluation sequence is performed.

8. The charged particle beam device according to claim 1, wherein
the calculation unit generates an observation image of the transistor using the detection signal obtained in the process of controlling the conductive state of the transistor, and
the calculation unit measures the on/off characteristic of the transistor based on a luminance value of an image of the transistor on the observation image.

9. The charged particle beam device according to claim 1, wherein
the light irradiation unit includes at least one of
a first light source configured to emit the light having a first wavelength and a second light source configured to emit the light having a second wavelength,
a light source configured to emit the light and a wavelength converter configured to convert the wavelength of the light,
a light source capable of emitting both the light having the first wavelength and the light having the second wavelength, and
a light source configured to emit the light having a plurality of wavelength components and a wavelength filter configured to select any one of the wavelength components.

10. The charged particle beam device according to claim 1, wherein
the calculation unit provides a user interface, and
the user interface presents at least one of
a charged particle beam irradiation condition input unit configured to input an irradiation condition of the charged particle beam,
a light irradiation condition input unit configured to input an irradiation condition of the light,
an observation image of the sample, and
a result of an inspection of the transistor.

11. The charged particle beam device according to claim 5, wherein
the calculation unit provides a user interface that presents the in-plane distribution.

12. A measurement method for a sample by irradiating the sample with a charged particle beam, the measurement method comprising:
a step of irradiating the sample with the charged particle beam;
a step of irradiating the sample with light;
a step of detecting a secondary particle generated from the sample by irradiating the sample with the charged particle beam and outputting a detection signal indicating an intensity of the secondary particle; and
a step of processing the detection signal, wherein
the sample is a transistor formed on a semiconductor material,
in the step of irradiating the sample with the charged particle beam, a gate of the transistor is irradiated with the charged particle beam to inject charges to turn on the transistor,
in the step of irradiating the sample with the light, the transistor is irradiated with the light and charges of the transistor are initialized to control a conductive state of the transistor, and
in the step of processing the detection signal, an on/off characteristic of the transistor with respect to an injected charge amount into the transistor is measured using the detection signal obtained in a process of controlling the conductive state of the transistor.
